(19) United States
(12) Patent Application Publication
(10) Pub. No.: US 2019/0344670 A1
(43) Pub. Date: Nov. 14, 2019

(54) BATTERY THERMAL MANAGEMENT DURING CHARGING

(71) Applicant: Ford Global Technologies, LLC, Dearborn, MI (US)

(72) Inventors: Stephenson Tyler Mattmuller, Rochester Hills, MI (US); Dhanunjay Vejalla, Novi, MI (US); Mark J. Ferrel, Brighton, MI (US); John Peter Bilezikjian, Canton, MI (US)

(21) Appl. No.: 15/977,338

(22) Filed: May 11, 2018

(51) Int. Cl. B60L 11/18; B60L 11/00; H01L 35/30; H01M 10/613; H01M 10/625; H01M 10/6572; H01M 10/6554

(52) U.S. Cl. CPC B60L 11/1874; B60L 11/1816; B60L 11/002; H01L 35/30; Y10S 903/907; H01M 10/625; H01M 10/6572; H01M 10/6554; H01M 10/613

(57) ABSTRACT

A vehicle includes a traction battery, a cold plate, and a thermoelectric device including a pair of thermally conductive plates disposed between the battery and cold plate and separated by doped junctions. The thermoelectric device is configured to, responsive to flow of current through the junctions, drive a temperature difference between the conductive plates to transfer heat between the battery and cold plate.

### TECHNICAL FIELD

The present disclosure relates to systems and methods for thermal management of a traction battery during charging.

### BACKGROUND

The term “electric vehicle” may be used to describe vehicles having at least one electric motor for vehicle propulsion, such as battery electric vehicles (BEV), hybrid electric vehicles (HEV), and plug-in hybrid electric vehicles (PHEV). A BEV includes at least one electric motor, wherein the energy source for the motor is a battery that is re-chargeable from an external electric grid. An HEV includes an internal combustion engine and one or more electric motors, wherein the energy source for the engine is fuel and the energy source for the motor is a battery. In air HEV, the engine is the main source of energy for vehicle propulsion with the battery providing supplemental energy tier vehicle propulsion (the battery buffers file energy and recovers kinetic energy in electric form). A PHEV is like an HEV, but the PHEV has a larger capacity battery that is rechargeable from the external electric grid. In a PHEV, the battery is the main source of energy for vehicle propulsion until the battery depletes to a low energy level, at which time the PHEV operates like an HEV for vehicle propulsion.

### SUMMARY

A vehicle includes a traction battery, a cold plate, and a thermoelectric device including a pair of thermally conductive plates disposed between the battery and cold plate and separated by doped junctions. The thermoelectric device is configured to, responsive to flow of current through the junctions, drive a temperature difference between the conductive plates to transfer heat between the battery and cold plate.

A vehicle includes a traction battery, a cold plate, and a cooling arrangement including a first thermally conductive plate in contact with the traction battery, a second thermally conductive plate in contact with the cold plate, and doped junctions disposed between the conductive plates. The cooling arrangement is configured to, responsive to flow of current through the junctions, increase a temperature difference between the conductive plates to transfer heat from the battery to the cold plate.

A thermal management system includes a traction battery, a heat exchanger, a first thermally conductive plate in contact with the battery, a second thermally conductive plate in contact with the heat exchanger, and doped junctions disposed between the conductive plates and configured to, responsive to flow of current therethrough, drive a temperature difference between the conductive plates to transfer heat between the battery and heat exchanger.

### BRIEF DESCRIPTION THE DRAWINGS

FIG. 1A is a block diagram of a plug-in hybrid electric vehicle (PHEV) illustrating a typical drivetrain and energy storage components;

FIG. 1B is a block diagram illustrating a vehicle charging system;

FIG. 2A is a block diagram illustrating a parallel thermal management system layout;

FIG. 2B is a block diagram illustrating energy transfer of the parallel thermal management system;

FIG. 3A is a block diagram illustrating a series thermal management system layout;

FIG. 3B is a block diagram illustrating energy transfer of the series thermal management system;

FIG. 3C is a block diagram illustrating energy transfer of a thermoelectric device arranged in parallel;

FIG. 3D is a block diagram illustrating a thermal management system for a traction battery; and

FIG. 4 is a graph illustrating an energy transfer pattern during an example charging cycle of the series thermal management system.

### DETAILED DESCRIPTION

Embodiments of the present disclosure are described herein. It is to be understood, however, that the disclosed embodiments are merely examples and other embodiments may take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the present invention. As those of ordinary skill in the art will understand, various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

During traction battery charging at a predefined charge current rate, the traction battery may generate a predefined amount of heat. In one example, amount of heat or power generated by the traction battery during charging may be based on charge current rate and traction battery resistance, such that, for a given current I=200 A and a traction battery resistance R_{trac_batt}=0.05 mΩ, the amount of heat H may be H=I²*R_{trac_batt=}200 A*200 A*0.05 mΩ=2 kW. In another example, an off-board charger configured to charge a vehicle traction battery may transfer charge current at a rate approximately equal to 350 A, thus, causing the heat generated by the traction battery to be approximately equal to 6.1 kW.

An electrical air conditioning (eAC) unit may be configured to perform both cabin and traction battery cooling. In some instances, one or more solid-state devices may be applied to replace or supplement operation of the eAC unit to cool the traction battery. The solid-state devices, such as thermoelectric devices and other passive or active electrical components, may be suitable for thermal management of a traction battery assembly during charging. The transfer of energy to the traction battery during charging may cause voltage of the high voltage electric bus of the vehicle to increase. In some instances, a voltage operating range of an off-board charging unit may be greater than the corresponding operating range of the traction battery. The excess of energy provided by the off-board charger to the vehicle may, in some cases, be used to power auxiliary loads that support battery thermal management.

However, connecting the thermal electric devices/chillers/or a hybrid combination across high voltage positive and negative energy supply lines may use at least a portion of current delivered to the vehicle via the charging circuit. In other words, the amount of current delivered to the traction battery may be less than the amount of current delivered to the vehicle by the off-board charger. Moreover, during operation, a given thermoelectric device may generate an amount of heat that is approximately equal to an amount of heat the device transfers such that a coefficient of performance (COP) of the device may be approximately one (1).

In one example, supplying thermal management operating power in series with the traction battery charge current may cause the amount of heat transferred by the thermoelectric device to be greater than the amount of heat the device generates during operation. Thus, the COP of the thermoelectric device connected using a series arrangement may be greater than one (1). This implementation may further include energy density benefits over using other devices, such as chillers. In some instances, the series configuration may include a negative feedback loop such that cooling of the traction battery may be increased responsive to increase in charge current. Operating performance of the thermoelectric devices may be optimal responsive to temperature of the battery cells being less than a threshold.

In some examples, the thermoelectric device may be disposed between the traction battery and the battery cold plate. The thermoelectric device may be configured to replace or supplement operation of the chillier during a drive thermal management cycle and/or during battery charging. The off-board vehicle battery may include a charge voltage greater than 500V and maximum voltage range of the traction battery may be less than that of the off-board charger, e.g., 400V. Thus, a difference in power provided by the charger and power accepted by the traction battery may in some instances be greater than 10%.

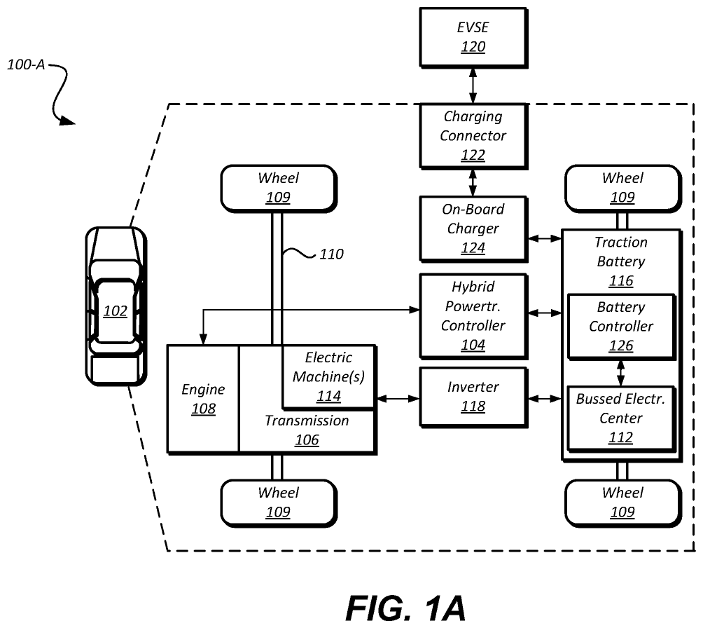

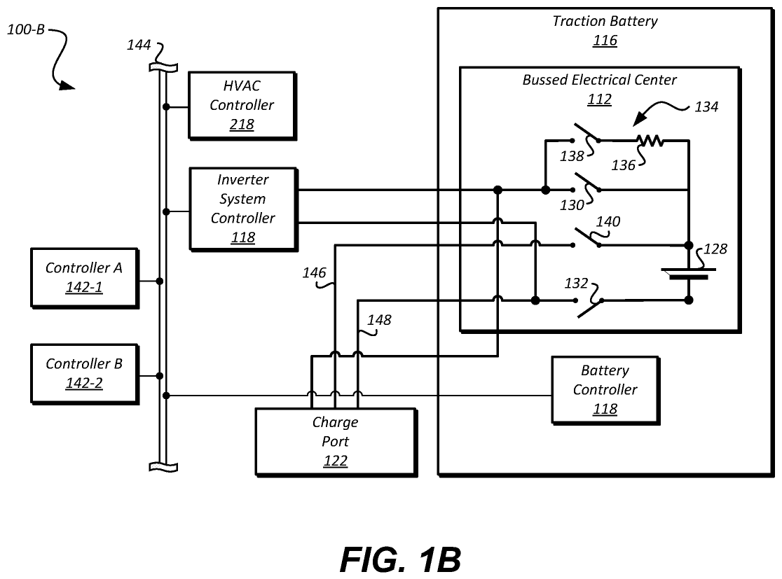

FIG. 1A illustrates an example diagram of a system 100-A of a hybrid electric vehicle (hereinafter, vehicle) 102 capable of receiving electric charge. The vehicle 102 may be of various types of passenger vehicles, such as crossover utility vehicle (CUV), sport utility vehicle (SUV), truck, recreational vehicle (RV), boat, plane or other mobile machine for transporting people or goods. It should be noted that the illustrated system 100-A is merely an example, and more, fewer, and/or differently located elements may be used.

The vehicle 102 may comprise a hybrid transmission 106 mechanically connected to an engine 108 and a drive shaft 110 driving wheels 109. A hybrid powertrain controller (hereinafter, powertrain controller) 104 may control engine 108 operating components (e.g., idle control components, fuel delivery components, emissions control components, etc.) and monitor status of the engine 108 operation (e.g., status of engine diagnostic codes). The hybrid transmission 106 may also be mechanically connected to one or more electric machines 114 capable of operating as a motor or a generator. The electric machines 114 may be electrically connected to an inverter system controller (hereinafter, inverter) 118 providing bi-directional energy transfer between the electric machines 114 and at least one traction battery 116.

As described in further detail in reference to at least FIG. 1B, the traction battery 116 may comprise one or more battery cells, e.g., electrochemical cells, capacitors, or other types of energy storage device implementations. The battery cells may be arranged in any suitable configuration and configured to receive and store electric energy for use in operation of the vehicle 102. Each cell may provide a same or different nominal threshold of voltage. The battery cells may be further arranged into one or more arrays, sections, or modules further connected in series, in parallel, or a combination thereof.

A bussed electrical center (BEC) 112 of the traction battery 116 may be electrically connected to the battery cells and may include a plurality of connectors and switches allowing a selective supply and withdrawal of electric energy to and from the traction battery 116. A battery controller 126 may be configured to monitor and control operation of the BEC 112, such as, but not limited to, by commanding the BEC 112 to selectively open and close one or more switches.

One or more components, e.g., capacitors, inside the traction battery 116, the inverter 118 system, the electric machines 114, and so on may be components configured to operate under high magnitude voltages and/or electrical currents. In one example, high voltage electrical cables, usually orange in color, may connect the battery 116, the inverter 118, the electric machines 114, and other components to one another. As one non-limiting example, a high voltage circuit may be a circuit operating using, voltage of greater than 50V.

The traction battery 116 typically provides a high voltage direct current (DC) output. In a motor mode, the inverter 118 may convert the DC output provided by the traction battery 116 to three-phase AC as may be required for proper functionality of the electric machines 114. In a regenerative mode, the inverter 118 may convert the three-phase AC output from the electric machines 114 acting as generators to the DC required by the traction battery 116. In addition to providing energy for propulsion, the traction battery 116 may provide energy for high voltage loads, such as an electric air conditioning (eAC) system and positive temperature coefficient (PTC) heater, and low voltage loads, such as electrical accessories, an auxiliary 12-V battery, and so on.

The vehicle 102 may be configured to recharge the traction battery 116 via a connection to a power grid. The vehicle 102 may, for example, cooperate with electric vehicle supply equipment (EVSE) 120 of a charging station to coordinate the charge transfer from the power grid to the traction battery 116. In one example, the EVSE 120 may have a charge connector for plugging into a charging connector 122 of the vehicle 102, such as via connector pins that mate with corresponding recesses of the charging connector 122. The charging connector 122 may be electrically connected to an on-board charger (hereinafter, charger) 124. The charger 124 may condition the power supplied from the EVSE 120 to provide the proper voltage and current levels to the traction battery 116. The charger 124 may be electrically connected to and in communication with the EVSE 120 to coordinate the delivery of power to the vehicle 102.

Temperature of one or more components of the traction battery 116 and charging system of the vehicle 102 may increase during charging. Cabin conditioning may be further provided during energy transfer to charge the traction battery 116. In some instances, one or more components configured to both cool the traction battery 116 and provide thermal management of the vehicle 102 interior at a same time. In some other instances, the cooling and conditioning components may be powered by on-vehicle energy sources, such as, but not limited to, the traction battery 116, the auxiliary low voltage battery, and so on. In still other instances, off-board sources, e.g., stand-alone charger, may be configured to power the cooling and conditioning components during charging of the vehicle 102.

Each of the HVAC controller 218 and the battery controller 126 may be electrically connected to and in communication with one or more other vehicle controllers 142, such as the inverter 118, the charger 124, and so on. The HVAC controller 218, the battery controller 126, and other vehicle controllers 142 may be further configured to communicate with one another and with other components of the vehicle 102 via one or more in-vehicle networks 144, such as, but not limited to, one or more of a vehicle controller area network (CAN), an Ethernet network, and a media oriented system transfer (MOST), as some examples.

FIG. 1B illustrates an example charging system 100-B of the vehicle 102. The vehicle 102 may be configured to connect to the EVSE 120 to charge the traction battery 116. In one example, the vehicle 102 may be configured to receive one or more power types, such as, but not limited to, single- or three-phase AC power and DC power. The vehicle 102 may be configured to receive different levels of AC and DC voltage including, but not limited to, Level 1 120-volt (V) AC charging, Level 2 240V AC charging, Level 1 200-450V and 80 amperes (A) DC charging, Level 2 200-450V and up to 200A DC charging, Level 3 200-450V and up to 400A DC charging, and so on. Time required to receive a given amount of electric charge may vary among the different charging methods. In some instances, if a single-phase AC charging is used, the traction battery 116 may take several hours to replenish charge. As another example, same amount of charge under similar conditions may be transferred in minutes using other charging methods.

In one example, both the charging connector 122 and the EVSE 120 may be configured to comply with industry standards pertaining to electrified vehicle charging, such as, but not limited to, Society of Automotive Engineers (SAE) J1772, J1773, J2954, International Organization for Standardization (ISO) 15118-1, 15118-2, 15118-3, the German DIN Specification 70121, and so on. In one example, the recesses of the charging connector 122 may include a plurality of terminals, such that first and second terminals may be configured to transfer power using Levels 1 and 2. AC charging, respectively, and third and fourth terminals may be DC charging terminals and may be configured to transfer power using Levels 1, 2, or 3 DC charging.

Differently arranged connectors having more or fewer terminal are also contemplated. In one example, the charging connector 122 may include terminals configured to establish a ground connection, send and receive control signals to and from the EVSE 120, send or receive proximity detection signals, and so on. A proximity signal may be a signal indicative of a state of engagement between the charging connector 122 of the vehicle 102 and the corresponding connector of the EVSE 120. A control signal may be a low-voltage pulse-width modulation (PWM) signal used to monitor and control the charging process.

The charger 124 may be configured to initiate traction battery 116 charging responsive to receiving a corresponding signal from the EVSE 120. In one example, the charger 124 may be configured to initiate charging responsive to a duty cycle of the request signal being greater than a predefined threshold.

The traction battery 116 may include a plurality of battery cells 128, e.g., electrochemical cells, configured to receive and store electric energy for use in operation of the vehicle 12. Each cell may provide a same or different nominal level of voltage. In some instances, several battery cells 128 may be electrically connected with one another into cell arrays, sections, or modules that are electrically connected in series or in parallel with one another. While the traction battery 116 is described herein to include electrochemical battery cells, other types of energy storage device implementations, such as capacitors, are also contemplated.

The BEC 112 may include a plurality of connectors and switches allowing the supply and withdrawal of electric energy to and from the battery cells 128 via a connection to corresponding positive and negative terminals.

The battery controller 126 is connected to the BEC 112 and controls the energy flow between the BEC 112 and the battery cells 128. For example, the battery controller 126 may be configured to monitor and manage temperature and state of charge of each of the battery cells 40. In another example, the battery controller 126 may command the BEC 112 to open or close a plurality of switches in response to temperature or state of charge in a given battery cell reaching a predetermined threshold. The battery controller 126 may further be in communication with other vehicle controllers (not shown), such as an engine control module (ECM) and transmission control module (TCM), and may command the BEC 112 to open or close a plurality of switches in response to a predetermined signal from the other vehicle controllers.

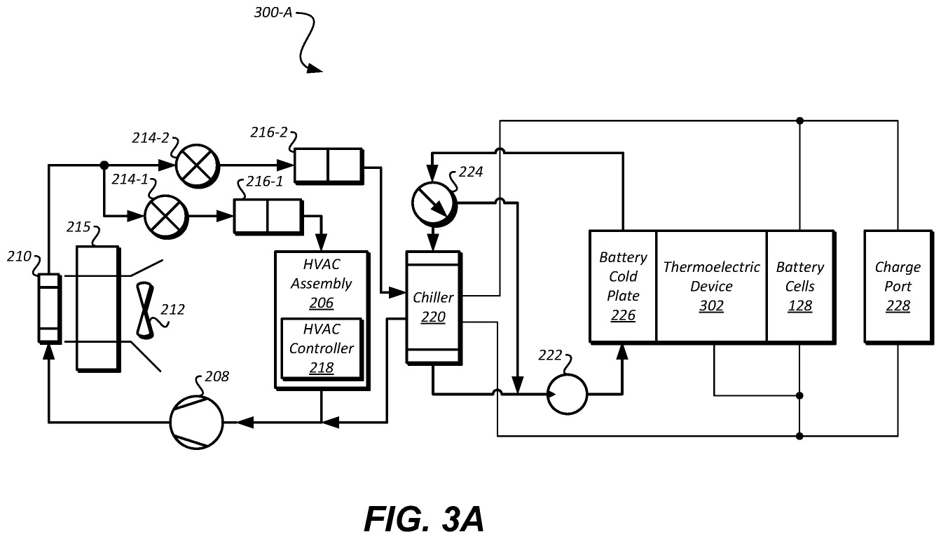

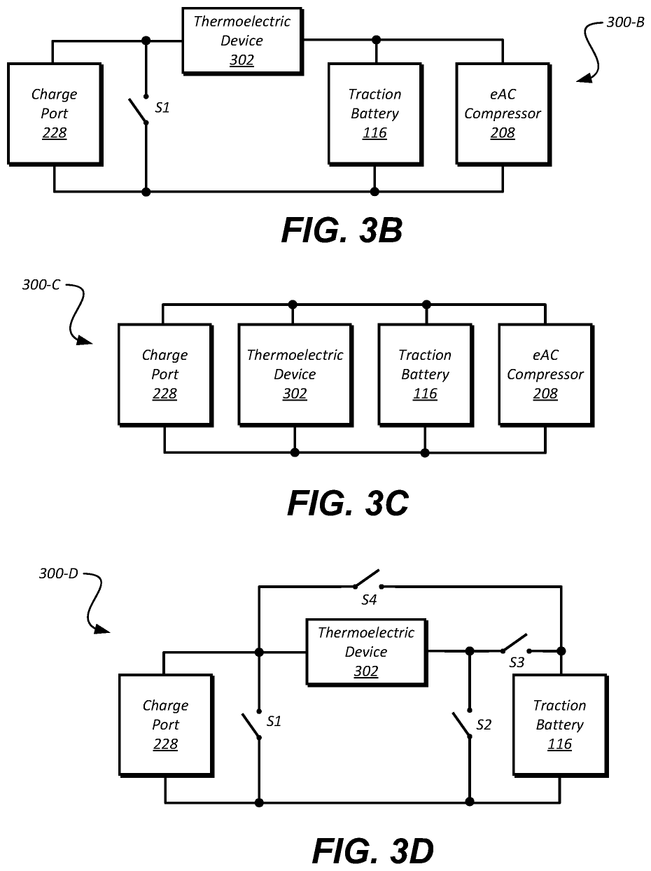

The battery controller 126 may also be in communication with the charger 124. For example, the charger 124 may send a signal to the battery controller 126 indicative of a charging request. The battery controller 126 may then command the BEC 112 to open or close a plurality of switches allowing the transfer of electric energy between the EVSE 120 and the traction battery 116. As will be described in further detail in reference to FIG. 3, the battery controller 126 may perform voltage matching prior to commanding the BEC 112 to open or close a plurality of switches allowing the transfer of electric energy.

The BEC 112 may comprise a positive main contactor 130 electrically connected to the positive terminal of the battery cells 128 and a negative main contactor 132 electrically connected to the negative terminal of the battery cells 128. In one example, closing the positive and negative main contactors 130, 132 allows the flow of electric energy to and from the battery cells 128. In such an example, the battery controller 126 may command the BEC 112 to open or close the main contactors 130, 132 in response to receiving a signal from the charger 124 indicative of a request to initiate or terminate battery 116 charging. In another example, the battery controller 126 may command the BEC 112 to open or close the main contactors 130, 132 in response to receiving a signal from another vehicle 102 controller, e.g., ECM, TCM, etc., indicative of a request to initiate or terminate transfer of electric energy to and from the traction battery 116.

The BEC 112 may further comprise a pre-charge circuit 134 configured to control an energizing process of the positive terminal. In one example, the pre-charge circuit 134 may include a pre-charge resistor 136 connected in series with a pre-charge contactor 138. The pre-charge circuit 134 may be electrically connected in parallel with the positive main contactor 130. When the pre-charge contactor 138 is closed the positive main contactor 130 may be open and the negative main contactor 132 may be closed allowing the electric energy to flow through the pre-charge circuit 134 and control an energizing process of the positive terminal.

In one example, the battery controller 126 may command BEC 112 to close the positive main contactor 130 and open the pre-charge contactor 138 in response to detecting that voltage level across the positive and negative terminals reached a predetermined threshold. The transfer of electric energy to and from the traction battery 116 may then continue via the positive and negative main contactors 130, 132. For example, the BEC 112 may support electric energy transfer between the traction battery 116 and the inverter 118 during either a motor or a generator mode via, a direct connection to conductors of the positive and negative main contactors 130, 132.

In another example, the battery controller 126 may enable energy transfer to the high-voltage loads, such as compressors and electric heaters, via a direct connection to the positive and negative main contactors 130, 132. Although not separately illustrated herein, the battery controller 126 may command energy transfer to the low-voltage loads, such as an auxiliary 12V battery, via a DC/DC converter connected to the positive and negative main contactors 130, 132.

For simplicity and clarity AC charging connections between the charging connector 122 and the traction battery 116 have been omitted. In one example, the main contactors 130, 132 in combination with the pre-charge circuit 134 may be used to transfer AC energy between the EVSE 120 and the traction battery 116. For example, the battery controller 126 may be configured to command the opening and closing of the main contactors 130, 132 in response to receiving a signal indicative of a request to initiate an AC charging.

The BEC 112 may further comprise a charge contactor 140 electrically connected to the positive terminal. The BEC 112 may close the negative main contactor 132 and close the charge contactor 140 in response to a signal indicative of a request to charge the battery. For example, the battery controller 126 may command the BEC 112 to close the negative main contactor 132 and to close the charge contactor 140 in response to receiving a signal from the charger 124 indicative of a request for battery charging. The battery controller 126 may selectively command the BEC 112 to open the negative main contactor 132 and to open the charge contactor 140 in response to receiving a notification of a charging completion.

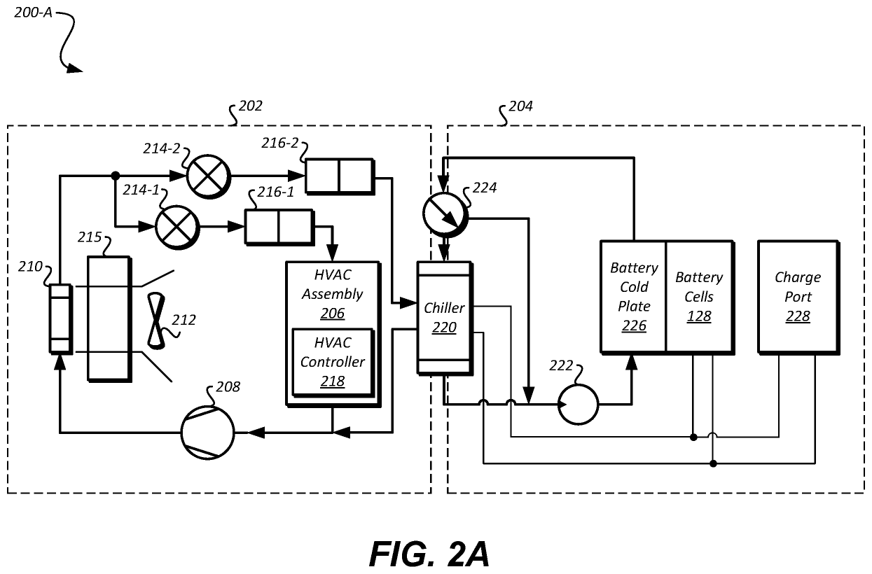

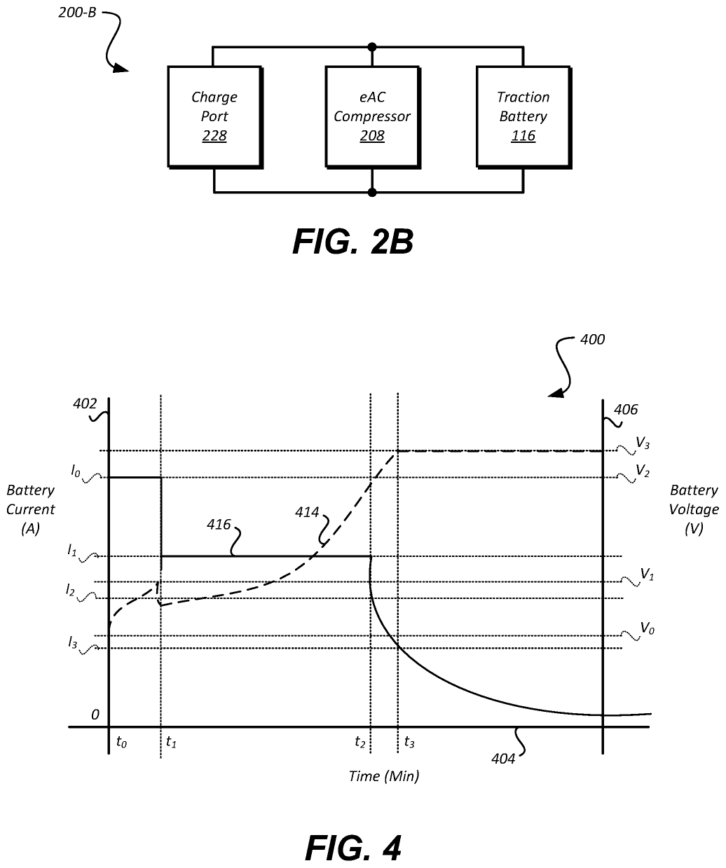

FIG. 2A illustrates an example thermal management system 200-A. The system 200-A may include a cabin cooling loop 202 configured to regulate interior cabin climate of the vehicle 102 and a component cooling loop 204 that performs thermal management of the traction battery 116, one or more subcomponents of the traction battery 116, and/or one or more components related to charging and discharging the traction battery 116. In one example, each loop 202, 204 may circulate one or several liquid or gaseous substances. The substance or a mixture of substances may undergo one or more physical or chemical state changes that may, among other effects, assist in transferring energy or heat from one portion of a given loop or another portion of that loop.

In some instances, the cabin and component cooling loops 202, 204 may be physically or chemically isolated from one another, such that matter circulated in the cabin cooling loop 202 does riot interact with matter circulated in the component cooling loop 204. In some other instances, the cabin and component cooling loops 202, 204 may be joined together (interlinked) or include one or more common (or shared) components, such that the corresponding substances being circulated may wholly or partially mix with one another. In still other instances, each of the corresponding substances of the cabin and component cooling loops 202, 204 may enter and exit a given shared component at different times from one another, such that no mixing occurs.

In one example, the cabin cooling loop 202 may include a heating ventilation and air conditioning (HVAC) assembly 206, an electrical air conditioning (eAC) compressor 208, a condenser 210, a shutoff valve 214-1, and a thermal expansion valve 216-1. The HVAC assembly 206 includes one or more components, such as, but not limited to, an evaporator core, a heater core, a blower motor, and so on, each connected to corresponding ducts, vents, and air flow passages configured to deliver, withdraw, and circulate air to make climate control adjustments or to maintain or establish climate control settings.

In some examples, an HVAC controller 218 of the HVAC assembly 206 may be electrically connected to in-vehicle HVAC user controls, a plurality of sensors, e.g., temperature, humidity, and sun load sensors, and one or more duct doors or duct door actuators. The HVAC controller 218 may be configured to monitor and control operation of the climate control system based on signals from the sensors and the user controls. As one example, the HVAC controller 218, responsive to a request from a given user control, may be configured to operate an actuator to move a duct door connected thereto to a predefined duct door position consistent with the request. As another example, the HVAC controller 218 may control operation of the interior climate control system based on a signal from one or more other vehicle 102 controllers, such as, but not limited to, from the powertrain controller 104, the inverter 118, the charger 124, the battery controller 126 and so on.

The eAC compressor 208 may be configured to compress vapor output by the evaporator of the HVAC assembly 206 and transfer the compressed vapor to the condenser 210. The HVAC controller 218 may be configured to monitor and control operation of the shutoff valves 214-1 and 214-2. In one example, the HVAC controller 218 may be configured to selectively open and close at least one of the shutoff valves 214-1 and 214-2, such that condensate output by the condenser 210 may be transferred to the corresponding expansion valves 216-1 and 216-2. Output of the first expansion valve 216-1 may be directed to the evaporator of the HVAC assembly 206 and output of the second expansion valve 216-2 may be directed to a chiller 220.

The chiller 220 may include a plate heat exchanger and may be configured to absorb heat from the refrigerant output by the second expansion valve 216-2 and transfer the cooled refrigerant to the eAC compressor 208. Thus, in some examples, the chiller 220 may be configured to supplement thermal management of the vehicle 102 cabin interior. Additionally or alternatively, the chiller 220 may be configured to receive output of a proportional valve 224 transferring coolant from a battery cold plate 226 and may, thereby, to transfer heat to cool the traction battery 116. In still other examples, the refrigerant circulating in the cabin cooling loop 202 and the coolant of the component cooling loop 204, when passing through the chiller 220, may exchange heat with one another, such that, but not limited to, the refrigerant may be used to cool the traction battery 116 and the coolant may be used to cool cabin interior.

A pump 222 of the component cooling loop 204 may be connected at the output of the chiller 220 and may be configured to direct coolant to the battery cold plate 226. The HVAC controller 218 may be configured to monitor and control operation of the pump 222. In one example, the HVAC controller 218 may selectively activate the pump 222, responsive to cabin temperature and/or the traction battery temperature being less a corresponding temperature threshold, and may deactivate the pump 222, responsive to one or both temperatures being less than the corresponding temperature thresholds.

The battery cold plate 226 may be disposed adjacent to and in contact with the battery cells 128 and may be configured to provide thermal management of the battery cells 128 during vehicle 102 operation and/or the traction battery 116 charging. In one example, coolant, or another liquid or gaseous substance or mixture of substances, passing through the battery cold plate 226 may transfer heat generated by the battery cells 128 during charging to cool the battery 116. A proportional valve 224 connected at the output of the battery cold plate 226 may be configured to direct coolant from the battery cold plate 226 to one of the chiller 220 and the pump 222.

FIG. 2B illustrates a power supply system 200-B for the eAC compressor 208 of the vehicle 102. In one example, the eAC compressor 208 and the traction battery 116 may be connected electrically in parallel to one another and connected electrically in parallel to a charge port 228. Flow of current through the charge port 228, such as, but not limited to, when the traction battery 116 is being charged using an off-board charger, may power the eAC compressor 208 connected electrically in parallel thereto. In some instances, current used to power the eAC compressor 208 may cause current transferred to the traction battery 116 by the charge port 228 to be less than current received by the charge port 228, e.g., from an off-board charger.

FIG. 3A illustrates a thermal management arrangement 300-A for the traction battery 116 of the vehicle 102. The arrangement 300-A may include a thermoelectric device 302 connected electrically in series between the battery cells 128 and the charge port 228 and configured to cool the battery cells 128 during charging.

The thermoelectric device 302 may be a solid-state device configured to convert heat energy to electric energy and vice versa. In one example, the thermoelectric device 302 includes two dissimilar thermally conducting plates. The plates of the thermoelectric device 302 may be joined by electrically conducting p-doped and n-doped junctions. In some instances, the junctions are placed electrically in series and thermally in parallel with one another. One or more portions of the thermoelectric device 302 may be made with bismuth telluride or another material having a high thermal conductivity.

Based on the Peltier effect, responsive to flow of current through the thermoelectric device 302, temperature of a first plate may increase and temperature of a second plate may decrease. Furthermore, when connected to a load, a temperature difference between the two plates produces a voltage difference based on the Seebeck effect. The thermoelectric device 302 may, thereby, be adapted in some applications as an energy generator.

In one example, one plate of the thermoelectric device 302 may be disposed to contact the battery cells 128 and the other plate may be disposed to contact the battery cold plate 226. In another example, the thermoelectric device 302 may be powered using flow of current transferred by the charge port 228, such that the plate in contact with the battery cells 128 transfers heat generated by the cells 128 to the plate in contact with the battery cold plate 226. Thus, the thermoelectric device 302 disposed between the battery cold plate 226 and the battery cells 128 may be used to cool the battery cells 128 during battery charging.

FIG. 3B illustrates a power supply system 300-B for the thermoelectric device 302 of the vehicle 102. In one example, the thermoelectric device 302 may be connected electrically in series between the traction battery 116 and the charge port 228. Flow of current through the charge port 228, such as, but not limited to, when the traction battery 116 is being charged using the off-board charger, may power the thermoelectric device 302 connected electrically in series thereto. In some instances, current flowing through the thermoelectric device 302 may be approximately equal to both current transferred to the traction battery 116 by the charge port 228 and to current received by the charge port 228, e.g., from an off-board charger.

Additionally or alternatively, the system 300-B may include a switch S1 electrically in parallel between the charge port 228 and the traction battery 116. The switch S1 may be operated by the HVAC controller 218 or another vehicle 102 controller 142, such that the switch S1 is open during traction battery 116 charging and current flowing through the thermoelectric device 302 is approximately equal to each of current transferred to the traction battery 116 by the charge port 228 and current received by the charge port 228, e.g., from an off-board charger. Upon charge completion and/or during vehicle 102 propulsion or operation, the HVAC controller 218 may operate to close the switch S1 to power the thermoelectric device 302 using the traction battery 116 to cool the traction battery 116.

FIG. 3C illustrates a power supply system 300-C for the thermoelectric device 302 of the vehicle 102. In one example, the thermoelectric device 302 may be connected electrically in parallel between the traction battery 116 and the charge port 228. Flow of current through the charge port 228, such as, but not limited to, when the traction battery 116 is being charged using the off-board charger, e.g., such as the EVSE 120, may power the thermoelectric device 302 connected electrically in parallel therebetween. In some instances, current flowing through the thermoelectric device 302 may be approximately equal to a difference between current output by the charge port 228 and current received by the traction battery 116.

FIG. 3D illustrates a power supply system 300-D for the thermoelectric device 302 of the vehicle 102. In addition to the switch S1, as described, for example, in reference to at least FIG. 3B, the system 300-D may include the thermoelectric device 302 connected electrically in series between the charge port 228 and the traction battery 116 via a switch S3. A switch S2 may be connected electrically parallel between the thermoelectric device 302 and the traction battery 116 and a switch S4 may be connected between the charge port 228 and the battery 116 to bypass the thermoelectric device 302.

When the switch S3 is closed and the switches S1, S2, and S4 are open during battery charging, flow of current through the charge port 228 may power the thermoelectric device 302 connected electrically in series between the charge port 228 and the traction battery 116 to cool the traction battery 116. In some instances, when the switch S3 is closed and the switches S1, S2, and S4 are open during battery charging, current flowing through the thermoelectric device 302 may be approximately equal to each of current output by the charge port 228 and current received by the traction battery 116.

Upon charge completion and/or during vehicle 102 propulsion or operation, the HVAC controller 218 may command to open the switch S3 and close the switches S1, S2, and S4 to power the thermoelectric device 302 using the traction battery 116 to cool the traction battery 116. As another example, upon charge completion and/or during vehicle 102 propulsion or operation, the HVAC controller 218 may command to close the switches S1 and S3 and open the switches S2 and S4, such that the thermoelectric device 302 may be powered using the traction battery 116 to heat the traction battery 116.

FIG. 4 illustrates an example parameter behavior graph 400 during charging of the traction battery 116. In one example, vertical axis 402 and horizontal axis 404 of the graph 400 may illustrate a change in battery 116 current with respect to time, respectively, and vertical axis 406 may illustrate a change in battery 116 voltage during a same period of time relative to the change in current. In another example, the curve 414 may illustrate a change in battery voltage with respect to time and curve 416 may illustrate a change in battery current with respect to time. In some instances, the relative changes of battery 116 current and voltage, during charging, may be indicative of a period of time to fully charge the traction battery 116.

As one example, charging of the traction battery 116 may begin at a time to when battery voltage is V₀ and battery current is I₀. At a time t₁, the battery voltage may be V₁, wherein V₁ is greater than V₀ by a predefined voltage amount, and the battery current is I₁, wherein I₁ is less than I₀ by a predefined current amount. The battery current I may decrease to I₂ at a time t₂, when the battery voltage is V₂, wherein I₂<I₁<I₀ and V₂>V₁>V₀. At a time t₃, the battery voltage may be V₃ that may be approaching a full charge of the traction battery 116 and the battery current may be I₃, wherein I₃<I₂<I₀ and V₃>V₂>V₁V₀.

The curves 416 and 414 may be indicative of the relative changes of battery 116 current and voltage during charging, respectively, wherein thermal management of the traction battery 116 during charging excludes the thermoelectric device connected between the charge port and the battery 116. Additionally or alternatively, the curves 416 and 414 may be indicative of the behavior of the battery cells during charging, wherein thermal management includes powering the thermoelectric device 302, connected in series between the charge port and the traction battery 116, using flow of current from the off-board charger, e.g., the EVSE 120. Thus, in some instances, the thermoelectric device 302 connected in series may operate to cool the traction battery 116 during charging without increasing a period of time to fully charge the battery 116.

In other instances, operating the thermoelectric device 302 connected in series may remove necessity to operate components of the thermal management system electrically in parallel with the traction battery 116, e.g., the chiller 220, the eAC compressor 208, thereby, improving the traction battery 116 charge time. Said another way, the thermoelectric device 302 connected in series operates to cool the traction battery 116 such that a magnitude of current received by the traction battery 116 may be approximately equal to magnitude of current delivered by the charge port 228, whereas components connected in parallel cool the battery 116 such that current received by the traction battery 116 may be less than current delivered by the charge port 228.

The processes, methods, or algorithms disclosed herein may be deliverable to or implemented by a processing device, controller, or computer, which may include any existing programmable electronic control unit or dedicated electronic control unit. Similarly, the processes, methods, or algorithms may be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms may also be implemented in a software executable object. Alternatively, the processes, methods, or algorithms may be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

The words used in the specification are words of description rather than limitation, and it is understood that various changes may be made without departing from the spirit and scope of the disclosure. As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. A vehicle comprising:
a traction battery;
a cold plate; and
a thermoelectric device including a pair of thermally conductive plates disposed between the battery and cold plate and separated by doped junctions, the thermoelectric device configured to, responsive to flow of current through the junctions, drive a temperature difference between the conductive plates to transfer heat between the battery and cold plate.

2. The vehicle of claim 1 further comprising a controller configured to, responsive to the flow stopping, selectively open and close a plurality of switches to initiate flow of current from the battery through the junctions to transfer heat from the battery to the cold plate.

3. The vehicle of claim 2, wherein the opening and closing are further responsive to the battery providing propulsion energy.

4. The vehicle of claim 1 further comprising a charge port configured to provide the current.

5. The vehicle of claim 4, wherein the thermoelectric device and the port are electrically in series.

6. The vehicle of claim 4, wherein the thermoelectric device and the port are electrically in parallel.

7. The vehicle of claim 1, wherein one of the conductive plates is in contact with the traction battery.

8. The vehicle of claim 1, wherein one of the conductive plates is in contact with the cold plate.

9. A vehicle comprising:
a traction battery;
a cold plate; and
a cooling arrangement including a first thermally conductive plate in contact with the traction battery, a second thermally conductive plate in contact with the cold plate, and doped junctions disposed between the conductive plates, the cooling arrangement configured to, responsive to flow of current through the junctions, increase a temperature difference between the conductive plates to transfer heat from the battery to the cold plate.

10. The vehicle of claim 9 further comprising a controller configured to, responsive to the flow stopping, selectively open and close a plurality of switches to initiate flow of current from the battery through the junctions to transfer heat from the battery to the cold plate.

11. The vehicle of claim 9 further comprising a charge port configured to provide the current.

12. The vehicle of claim 11, wherein the arrangement and port are electrically in series.

13. The vehicle of claim 11, wherein the arrangement and port are electrically in parallel.

14. The vehicle of claim 13 wherein the opening and closing are further responsive to the battery providing propulsion energy.

15. A thermal management system comprising:
a traction battery;
a heat exchanger;
a first thermally conductive plate in contact with the battery;
a second thermally conductive plate in contact with the heat exchanger; and
doped junctions disposed between the conductive plates and configured to, responsive to flow of current therethrough, drive a temperature difference between the conductive plates to transfer heat between the battery and heat exchanger.

16. The system of claim 15, wherein the battery is configured to provide the flow of current.

17. The system of claim 15 further comprising a charge port configured to provide the flow of current.

18. The system of claim 17, wherein the doped junctions and port are electrically in series.

19. The system of claim 17, wherein the doped junctions and port are electrically in parallel.
